(19) United States
(12) Patent Application Publication
(10) Pub. No.: US 2021/0096461 A1
(43) Pub. Date: Apr. 1, 2021

(54) DEFECT REPAIRING METHOD AND TEMPLATE MANUFACTURING METHOD

(71) Applicant: KIOXIA CORPORATION, Tokyo (JP)

(72) Inventor: Ai KUMADA, Yokohama Kanagawa (JP)

(21) Appl. No.: 16/803,146

(22) Filed: Feb. 27, 2020

(30) Foreign Application Priority Data
Sep. 26, 2019 (JP) 2019-176093

(51) Int. Cl. G03F 7/00; H01L 21/027

(52) U.S. Cl. CPC G03F 7/0002; H01L 21/027

(57) ABSTRACT

According to one embodiment, a defect repairing method includes acquiring defect location information for a pattern on a first substrate. The defect location information provides a position at which the pattern on the first substrate does not match an intended pattern. A region on the first substrate is selected to include a defective pattern portion on the first substrate. The region is selected based on the acquired defect location information. The selected region is processed to remove the defective pattern portion of the pattern from the first substrate. The pattern remaining on the processed first substrate is transferred to a second substrate. A region on the second substrate corresponding to the selected region of the first substrate is then patterned to provide a pattern in the region corresponding to the intended pattern.

### CROSS-REFERENCE TO RELATED APPLICATION

This application is based upon and claims the benefit of priority from Japanese Patent Application No. 2019-176093, filed Sep. 26, 2019, the entire contents of which are incorporated herein by reference.

### FIELD

Embodiments described herein relate generally to a defect repairing method and a template manufacturing method.

### BACKGROUND

Nanoimprint lithography has been proposed as a pattern transfer method alternative to photolithography in manufacturing semiconductor devices. In nanoimprint lithography, a template on which a pattern has been formed is directly pressed onto a substrate that has been coated with an organic material. The pattern from the template is transferred into the organic material on the substrate. If a defect is on the template, the defect will also be transferred onto the substrate. To address these possible defects, template manufacturing processes include a defect repair or correction process.

### DESCRIPTION OF THE DRAWINGS

FIG. 1 depicts a template according to a first embodiment.

FIG. 2 is a flowchart of a defect repairing method according to a first embodiment.

FIG. 3 depicts aspects of a defect repairing method according to a first embodiment.

FIG. 4 depicts other aspects of the defect repairing method according to a first embodiment.

FIG. 5 depicts other aspects of the defect repairing method according to a first embodiment.

FIGS. 6A to 6E depicts other aspects of the defect repairing method according to a first embodiment.

FIG. 7 depicts other aspects the defect repairing method according to a first embodiment.

FIG. 8 depicts other aspects the defect repairing method according to a first embodiment.

FIG. 9 is a flowchart of a defect repairing method according to a second embodiment.

FIGS. 10-14 depict aspects of a defect repairing method according to a second embodiment.

### DETAILED DESCRIPTION

Example embodiments provide a defect repairing method and a template manufacturing method that can facilitate repair.

In general, according to one embodiment, a defect repairing method includes acquiring defect location information for a pattern on a first substrate. The defect location information provides a position at which the pattern on the first substrate does not match an intended pattern. A region on the first substrate is then selected to include a defective pattern portion of the pattern on the first substrate. The region is selected based on the acquired defect location information. The selected region is then processed to remove the defective pattern portion of the pattern from the first substrate. The pattern on now the processed first substrate is transferred to a second substrate. A region on the second substrate corresponding to the selected region of the first substrate is then patterned. The patterning of the region on the second substrate provides a pattern in the region corresponding to the intended pattern. In this context, patterning can comprise etching and/or deposition of material in the region according to the defect type being repaired. The patterning can comprise and/or be performed with charged particle beam processing.

Embodiments of the present disclosure will be described hereinafter with reference to the drawings. In the drawings, the same or substantially similar elements are denoted by same reference symbols. It should be noted that the drawings are schematic and depicted relationships between various thicknesses and/or planar dimensions and the like may differ from actual ones.

### FIRST EMBODIMENT

A defect repairing method according to the first embodiment is used to repair a pattern defect generated in, for example, template manufacturing processes.

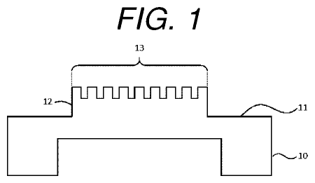

A template having a defect which is repaired in the present embodiment will be described. FIG. 1 is an explanatory cross-sectional view of the template of the present embodiment. The template is used in nanoimprint lithography as mold (original plate) and is subjected to microfabrication processes for manufacturing a semiconductor device or the like. In a case of UV imprint lithography, a main component of the template is, for example, quartz (which is a UV transparent material).

In the example shown in FIG. 1, the template has a mesa structure 12 on a principal surface 11 of a base material section 10. A pattern surface 13, on which a pattern having concave portions and convex portions (e.g., protrusions and recesses) is formed, is provided as an upper surface of the mesa structure 12.

Types of the template include a master template that serves as an original plate for manufacturing another template (a replica template) and a replica template manufactured by transferring a pattern from the master template onto the replica template. In semiconductor device manufacturing, the replica template is generally used. In manufacturing a replica template, if a defect pattern is on the master template, the defect pattern will be transferred to the replica template and it is, therefore, necessary to repair the defect pattern.

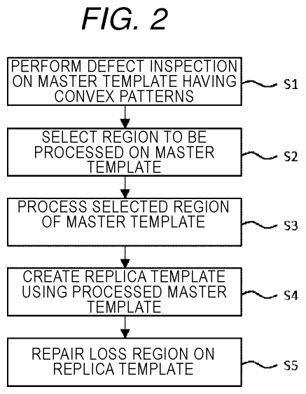

The defect repairing method according to the first embodiment will be described below with reference to FIGS. 2 to 8. The defect repairing method of this first embodiment is carried out as part of replica template manufacturing processes.

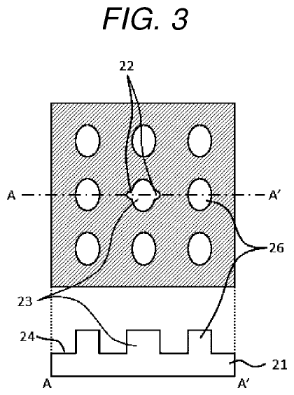

FIG. 2 is a flowchart showing the defect repairing method according to the first embodiment. In addition, FIGS. 3 to 8 are explanatory diagrams of the defect repairing method according to the first embodiment. In each of FIGS. 3 to 5 and 7 to 8, an upper part depicts a plan view and a lower part depicts a cross-sectional view.

### Step S1, FIG. 3

A defect inspection is performed on a master template 21. The defect inspection can be performed using a well-known defect inspection apparatus. The defect inspection apparatus detects a part on the pattern surface 13 (shown in FIG. 1) of the template that is different from a desired pattern represented by design data or the like as a defect, and extracts the detected defect as defect location information.

Types of the pattern defect include a “black defect” (that is an unnecessary/unintended pattern portion), a redundant pattern, or a foreign substance (e.g., particle) on the template and a “white defect” which correspond to a lost or missing portion of the intended pattern for the template.

In this example, a case of discovering/detecting a defect pattern 23 containing black defects 22, shown in FIG. 3, as a result of the defect inspection will be described. FIG. 3 shows a particular part of the pattern surface 13 (shown in FIG. 1) containing the defect pattern 23. As shown in FIG. 3, a plurality of convex-shaped patterns (hereinafter, referred to as “convex patterns” or protrusions) are formed on a reference surface 24 of the master template 21. The convex patterns include the defect pattern 23 and normal patterns 26.

While the convex patterns provided on the reference surface 24 are illustrated as pillar structures in the present embodiment, the convex patterns formed on the reference surface 24 are not limited to the pillar structures and may be, for example, linear structures extending along the reference surface 24.

Furthermore, the master template 21 depicted in FIG. 3 does not encompass the entire template but rather only a particularly relevant part of the master template 21, and subsequent drawings will similarly depict only the particularly relevant part of the master template 21 or other templates.

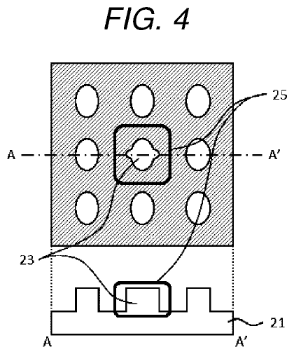

### Step S2, FIG. 4

To process the defect pattern 23, a to-be-processed region 25 is set on the pattern surface 13 (shown in FIG. 1) of the master template 21. A processing apparatus is used to set the to-be-processed region 25.

The defect location information acquired in Step S1 is input to the processing apparatus. As shown in FIG. 4, the processing apparatus sets a region containing the entire defect pattern 23 on the master template 21 as a to-be-processed region 25 on the basis of the defect location information. A size of the region 25 may be arbitrarily set as long as the region 25 contains the entire defect pattern 23.

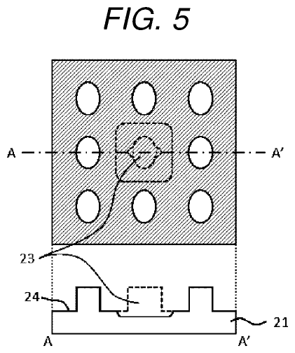

### Step S3, FIGS. 4 and 5

The processing apparatus processes the region 25 containing the defect pattern 23. More specifically, patterns in the region 25 are all removed using the processing apparatus. A broken-line (dashed-line) part in FIG. 5 denotes the removed defect pattern 23 and the portions surrounding the defect pattern 23 in the region 25. The region 25 can be processed by a well-known method. The method of processing the region 25 will be further described. The defect pattern 23 in the region 25 is etched to a depth corresponding to the reference surface 24 using the processing apparatus. The etching is performed using, for example, a charged particle beam and assist gas such as xenon difluoride (XeF₂). It is contemplated that the charged particle beam can be, for example, an electron beam (EB) or an ion beam (e.g., Gas Field Ion Source-Focused Ion Beam).

At time of this etching, the charged particle beam is emitted over the entire region 25 containing the defect pattern 23; thus, the final processed region is often slightly depressed beyond the reference surface 24 as shown in FIG. 5.

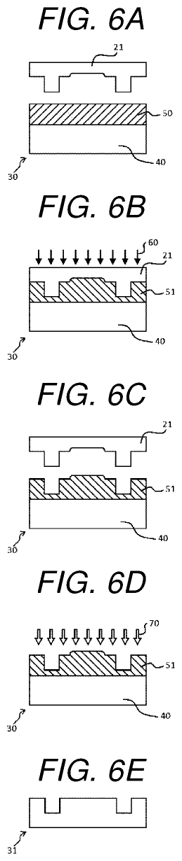

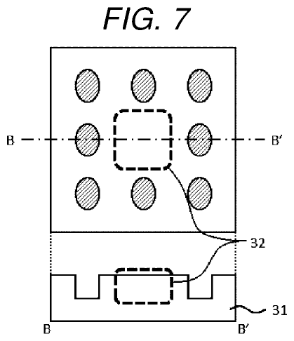

### Step S4, FIGS. 6A to 6E and 7

A replica template 31 is created using the now processed master template 21. The replica template 31 is created using, for example, nanoimprint lithography. As shown in FIGS. 6A to 6E, the replica template 31 having an inverted (inverse) pattern with respect to the pattern on the master template 21 is created from the processed master template 21 using the processed master template 21 as an original plate.

For example, as shown in FIG. 6A, a transfer target substrate 30 is prepared with a photocurable resin layer 50 formed on a substrate 40.

Next, as shown in FIG. 6B, the processed master template 21 is brought into contact with the resin layer 50 on the substrate 40, and light 60 is used to cure the resin layer 50, thereby forming a resin pattern 51. Subsequently, as shown in FIG. 6C, the master template 21 is released.

Next, as shown in FIG. 6D, the substrate 40 is etched using the resin pattern 51 as a mask. The substrate 40 is etched by, for example, anisotropic dry etching, such as reactive ion etching (RIE) using a reactive gas 70, such as oxygen gas. As a result of the etching, the replica template 31 having the inverted pattern with respect to the master template 21 is created as shown in FIG. 6E. While a depression is present in region 25 as generated in Step S3 and is thus transferred onto the resin pattern 51, the shape of the transferred pattern with the depression is not actually transferred into the substrate 40 in subsequent processing by etching and is therefore essentially ignorable after this processing.

As shown in FIG. 7, a transfer target region on the replica template 31 corresponding to the region 25 on the master template 21 is a generally flat region 32 lacking a pattern recessing.

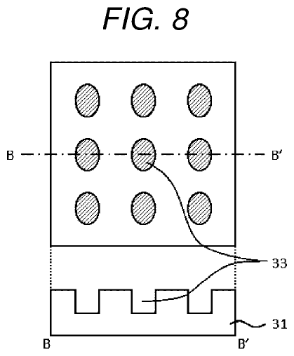

### Step S5, FIGS. 7 and 8

The region 32 of the replica template 31 shown in FIG. 7 can thus be repaired (that is, have the intended design pattern or the like formed therein) using a well-known repairing apparatus. It is possible to use the same apparatus as the processing apparatus used in Step S3 as the repairing apparatus.

As a result of the repair, the region 32 is altered to a repaired pattern 33 as shown in FIG. 8. The region 32 can be repaired by a well-known method. The region 32 may be repaired to have a size, a height, and the like corresponding to the desired pattern originally intended for the region 32. In some instances, the pattern(s) in region(s) surrounding the region 32 can be utilized as a guide pattern for the repaired pattern 33. The replica template 31 having a desired pattern shape can be thereby manufactured.

According to the defect repairing method of the first embodiment, the pattern surface of the master template is transferred onto the replica template only after the defect pattern in the region 25 is entirely removed from the master template 21. Owing to this technique, as compared with a method that corrects the defect pattern to the desired pattern after it has been transferred to the replica template, it is possible to simplify setting of repair conditions since the region to be repaired on the master template once processed results in a generally flat region, thus is a more easily processible region when formed on the replica template. Furthermore, it is possible to achieve an improvement in correction success rate since corrections/repairs to form the pattern on a generally flat surface are generally easier to perform than corrections of an already formed defect pattern on the replica template.

It is noted that the first embodiment is applicable to both white defects and black defects so long as the master template has convex patterns.

Moreover, the first embodiment is not limited to the defect repair of a template for imprinting and is also applicable to defect repair on other substrates though the defect repairing method in this example was adapted to templates for imprint lithography processes.

### SECOND EMBODIMENT

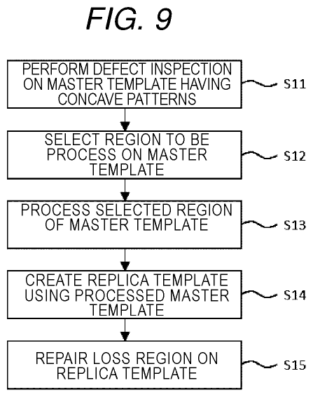

A defect repairing method according to a second embodiment will be described with reference to FIGS. 9 to 14. The defect repairing method according to the second embodiment differs from the defect repairing method according to the first embodiment in that a master template has concave-shaped patterns (hereinafter, referred to as “concave patterns” or recesses) and the template is processed and repaired not by etching but by film deposition.

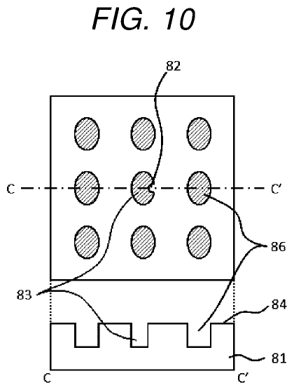

FIG. 9 is a flowchart showing the template defect repairing method according to the second embodiment. FIGS. 10 to 14 are explanatory diagrams of the template defect repairing method according to the second embodiment. In each of FIGS. 10 to 14, an upper portion of the figure depicts a plan view and a lower portion depicts a cross-sectional view. Explanation of aspects similar to those in the explanations for the first embodiment may be omitted in the following.

### Step S11, FIG. 10

A defect inspection is performed on a master template 81 having concave patterns.

A case of discovering a defect pattern 83 containing black defects 82, shown in FIG. 10, as a result of the defect inspection will be described. FIG. 10 shows part of the pattern surface 13 (shown in FIG. 1) containing the defect pattern 83. As shown in FIG. 10, a plurality of concave patterns are formed recessed from a reference surface 84 of the master template 81. The depicted concave patterns include the defect pattern 83 and normal patterns 86.

While the concave patterns provided on the reference surface 84 are illustrated as hole structures in the present embodiment, the concave patterns formed on the reference surface 84 are not limited to these hole structures and may be trench structures or the like.

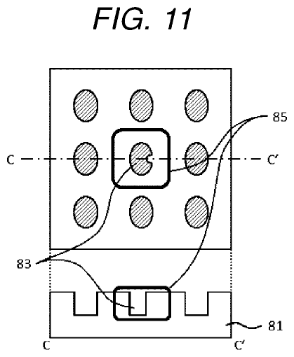

### Step S12, FIG. 11

To process the defect pattern 83, a region 85 is established on the pattern surface 13 of the master template 81. Since details of setting of the region 85 were already substantially described in relation to Step S2 of the first embodiment, further description thereof is omitted.

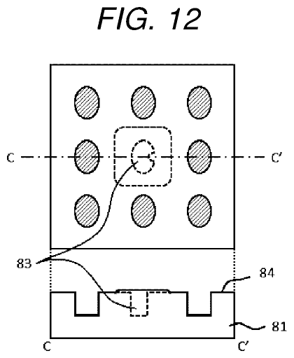

### Step S13, FIGS. 11 and 12

The processing apparatus processes the region 85 containing the defect pattern 83. More specifically, an interior of the concave pattern located in the region 85 is completely filled up by film deposition using the processing apparatus. A broken-line part (dashed line) in FIG. 12 denotes the defect pattern 83 has been completely filled up and portions surrounding the defect pattern 83 in the region 85 also include deposited material. The region 85 is processed by the well-known method. The method of processing the region 85 will be further described. A film is deposited into the defect pattern 83 in the region 85 to provide a fill depth corresponding to the reference surface 84. The film deposition is performed using, for example, a charged particle beam and gas such as tetraethoxysilane (TEOS). It is contemplated that the charged particle beam can be, for example, an electron beam or an ion beam. At time of this film deposition, the charged particle beam is radiated onto the entire region 85 containing the defect pattern 83; thus, the processed region 85 is often slightly elevated from the reference surface 84 as shown in FIG. 12.

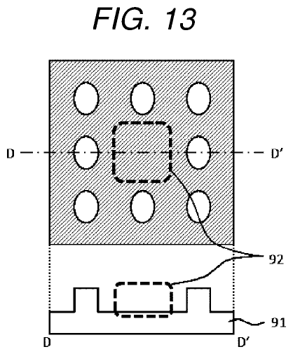

### Step S14, FIG. 13

A replica template 91 is created using the now processed master template 81. Since details of creation of the replica template 91 are similar to those already described in relation to Step S4 of the first embodiment, further description thereof is omitted.

As shown in FIG. 13, a transfer target region corresponding to the region 85 on the master template 81 is a generally flat region 92 without a pattern on the replica template 91.

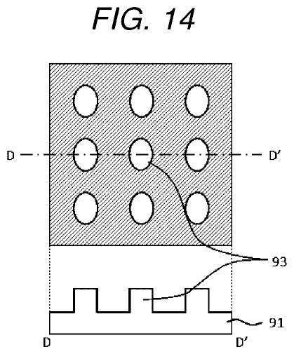

### Step S15, FIGS. 13 and 14

The region 92 on the replica template 91 shown in FIG. 13 has been repaired. It is possible to use the same apparatus as the processing apparatus used in Step S13 as the repairing apparatus.

As a result of the repair, the region 92 has been repaired to a corrected pattern 93 as shown in FIG. 14. The region 92 may be repaired to have a size, a height, and the like of a intended pattern. In some examples, a region(s) around the loss region 92 can be utilized as a guide pattern. The replica template 91 having a desired pattern shape can be thereby manufactured.

According to the template defect repairing method of the second embodiment, it is possible to simplify setting of repairing conditions and achieve an improvement in correction success rate similarly to the first embodiment.

It is noted that the second embodiment is applicable to both white defects and black defects so long as the master template has concave patterns.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A defect repairing method, comprising:
acquiring defect location information for a pattern on a first substrate, the defect location information providing a position at which the pattern on the first substrate does not match an intended pattern;
selecting a region on the first substrate to include a defective pattern portion of the pattern on the first substrate, the region being selected based on the acquired defect location information;
processing the selected region to remove the defective pattern portion of the pattern from the first substrate;
transferring the pattern on the processed first substrate to a second substrate; and
patterning a region on the second substrate corresponding to the selected region of the first substrate, the patterning of the region on the second substrate providing a pattern in the region corresponding to the intended pattern.

2. The defect repairing method according to claim 1, wherein the transferring includes performing imprint lithography on the second substrate using the first substrate as a template.

3. The defect repairing method according to claim 1, wherein processing the selected region includes removal of a portion of the first substrate using a charged particle beam.

4. The defect repairing method according to claim 1, wherein processing the selected region includes deposition of a material onto the first substrate and filling at least a portion of the defective pattern portion with the material, and the deposition is performed using a charged particle beam.

5. The defect repairing method according to claim 1, wherein patterning of the region on the second substrate uses a charged particle beam processing for etching.

6. The defect repairing method according to claim 1, wherein patterning of the region on the second substrate uses a charged particle beam processing for deposition.

7. An imprint template manufacturing method, comprising:
inspecting a pattern on a first substrate to provide defect location information for the pattern on the first substrate, the defect location information providing a position at which the pattern on the first substrate does not match an intended pattern;
designating a defective region on the first substrate based on the defect location information, the defective region encompassing a defective pattern portion of the pattern on the first substrate;
processing the designated defective region to remove the defective pattern portion of the pattern from the first substrate;
transferring the pattern on a second substrate using the processed first substrate; and
patterning a region on the second substrate corresponding to the designated defective region of the first substrate, the patterning of the region on the second substrate providing a pattern in the region corresponding to the intended pattern.

8. The imprint template manufacturing method according to claim 7, wherein the transferring of the pattern includes performing imprint lithography on the second substrate using the first substrate as a template.

9. The imprint template manufacturing method according to claim 7, wherein processing the designated defective region includes removal of a portion of the first substrate using a charged particle beam.

10. The imprint template manufacturing method according to claim 7, wherein processing the designated defective region includes deposition of a material onto the first substrate and filling at least a portion of the defective pattern portion with the material, and the deposition is performed using a charged particle beam.

11. The imprint template manufacturing method according to claim 7, wherein patterning of the region of the second substrate uses a charged particle beam for deposition.

12. The imprint template manufacturing method according to claim 7, wherein patterning of the region on the second substrate uses a charged particle beam for etching.

13. A method for transferring an intended pattern on a first template to a second template, comprising:
performing a defect inspection on a first template having a pattern of convex and concave portions on a surface thereof to locate a region on the surface at which the pattern does not match an intended pattern;
processing the first template to remove all pattern portions from the region located in the defect inspection, the region being substantially unpatterned after the processing;
patterning a second template using the processed first template to form an unrepaired pattern on the second template; and
repairing the unrepaired pattern on the second template by patterning a region on second substrate corresponding to the region located in the defect inspection on the first template.

14. The method according to claim 13, wherein processing the first template to remove all pattern portions from the region located in the defect inspection comprises removing pattern portions protruding from the surface of the first template.

15. The method according to claim 13, wherein processing the first template to remove all pattern portions from the region located in the defect inspection comprises filling pattern portions recessed into the surface of the first template with a material deposited onto the first template.

16. The method according to claim 13, wherein patterning the second template using the processed first template comprises performing imprint lithography on the second template with the processed first template.

17. The method according to claim 16, wherein patterning the second template further comprises etching into the second template.

18. The method according to claim 13, wherein the first template is a master template for imprint lithography processes.

19. The method according to claim 18, wherein the second template is a replica template for imprint lithography processes.

20. The method according to claim 13, wherein an upper surface of the region located in the defect inspection is recessed from the surface of the first template after the processing of the first template to remove all pattern portions from the region.
